(19) United States
(12) Patent Application Publication
(10) Pub. No.: US 2024/0328770 A1
(43) Pub. Date: Oct. 3, 2024

(54) DETECTOR DETECTION DEVICE AND MEASURING MACHINE

(71) Applicant: MITUTOYO CORPORATION, Kanagawa (JP)

(72) Inventors: Takayuki SHIMOJI, Tokyo (JP); Hideaki FUJIHARA, Kanagawa (JP); Toshihiro KANEMATSU, Miyazaki (JP)

(73) Assignee: MITUTOYO CORPORATION, Kanagawa (JP)

(21) Appl. No.: 18/613,643

(22) Filed: Mar. 22, 2024

(30) Foreign Application Priority Data
Mar. 31, 2023 (JP) 2023-059059

(51) Int. Cl. G01B 5/28; G01R 19/00

(52) U.S. Cl. CPC G01B 5/28; G01R 19/0038

(57) ABSTRACT

A detector detection device includes a detection circuit to which a detecting signal is input, via a connector of a measuring machine, from a detector connected to the connector, and a determination section that determines whether the detector is connected to the connector, in which the detection circuit includes a first ground having a first electric potential that is lower than a reference electric potential of the detector and a comparator that is electrically connected to the first ground, receives the detecting signal from the connector, and compares an input voltage and a predetermined threshold voltage, and the determination section determines based 10 on a binary signal output from the comparator whether the detector is connected to the connector.

### CROSS REFERENCE TO RELATED APPLICATIONS

The entire disclosure of Japanese Patent Application No. 2023-059059 filed Mar. 31, 2023 is expressly incorporated by reference herein.

### TECHNICAL FIELD

The present invention relates to a detector detection device and a measuring machine.

### BACKGROUND ART

There is conventionally known a measuring machine including: a stylus that comes into contact with a measurement target; a detector that outputs a detecting signal of which amplitude varies depending on displacement of the stylus; and a control unit that measures a surface texture or the like of the measurement target based on the detecting signal (see, for instance, Literature 1: JP 2021-42999 A). Such a measuring machine typically includes a replaceable detecting unit that includes the stylus and the detector so that a stylus suitable for measurement is usable. In the replacement of the detecting unit, a plug of the detecting unit is plugged into a connector of the measuring machine, which causes the detector to be electrically connected to the control unit of the measuring machine via the connector.

In the above measuring machine, however, the plug of the detecting unit may not be properly plugged into the connector or the plug may be almost detached from the connector accidentally, for instance. In such cases, the detector may not be electrically connected to the connector. When that happens, a user may not quickly understand why the measuring machine cannot perform measurement and it takes time to determine the cause. Further, the manufacturer of the measuring machine receives inquiries from users about the cause why the measuring machine cannot perform measurement, which puts a burden on the manufacturer to respond to the inquiries.

### SUMMARY OF THE INVENTION

An object of the invention is to provide a detector detection device configured to detect whether or not a detector is connected to a connector, and a measuring machine.

A detector detection device according to an aspect of the invention includes: a detection circuit to which a detecting signal is input, via a connector of a measuring machine, from a detector connected to the connector; and a determination section configured to determine whether or not the detector is connected to the connector, in which the detection circuit includes a first ground having a first electric potential that is lower than a reference electric potential of the detector and a comparator that is electrically connected to the first ground and that is configured to receive the detecting signal from the connector and compare an input voltage and a predetermined threshold voltage, and the determination section is configured to determine based on a binary signal output from the comparator whether the detector is connected to the connector.

In such a configuration, the detecting signal or the first ground is input to the comparator depending on whether the detector is electrically connected to the connector. This makes a difference in the input voltage to be input to the comparator depending on whether or not the detector is electrically connected to the connector. The comparator is thus capable of outputting the binary signal depending on whether or not the detector is electrically connected to the connector. This allows the determination section to determine based on the binary signal whether the detector is electrically connected to the connector.

Accordingly, a user easily understands the cause (i.e., poor connection between the connector of the measuring machine and the detector) of the measurement error in the measuring machine including such a detector detection device. Further, the burden on the manufacturer of the measuring machine to respond to the inquiries is reducible.

In the detector detection device according to the aspect of the invention, preferably, the detection circuit further includes a second ground having a second electric potential that is equal to the reference electric potential of the detector and a switching section that is selectively connected to one of the first ground and the second ground and is configured to perform switching of a reference electric potential of the comparator between the first electric potential and the second electric potential, and the detector detection device further includes a switching control section configured to control the switching performed by the switching section.

In such a configuration, the detection function can be turned on/off by performing the switching of the connection destination of the detection circuit between the first ground and the second ground. In the measuring machine including the detector detection device, the detection function is turned off by connecting the switching section to the second ground at the time of measurement, which reduces the effect of noise or the like on measurement.

In the detector detection device according to the aspect of the invention, preferably, the detection circuit further includes a filter that is configured to form the input voltage to be input to the comparator by attenuating an AC component of the detecting signal.

Such a configuration clearly defines the difference in the input voltage based on the presence or absence of the connection of the detector, facilitating the setting of the threshold voltage to be input to the comparator. Further, it is possible to more accurately determine whether the detector is electrically connected.

In the detector detection device according to the aspect of the invention, the first ground preferably has a ground potential.

Such a configuration makes a difference in the input voltage of the comparator based on the presence or absence of the connection of the detector and reduces electric power consumed in the detection circuit.

A measuring machine according to an aspect of the invention includes: any of the above detector detection devices; the connector; the detector that is removably connected to the connector and is configured to output the detecting signal depending on displacement of a surface of a measurement target; and a measurement section configured to measure a surface texture of the measurement target based on the detecting signal output from the detector.

Such a configuration provides the effects similar to those of the detector detection device described above.

In the measuring machine according to the aspect of the invention, preferably, the switching section is connected to the first ground in a case where the determination section performs the determination and is connected to the second ground in a case where the measurement section performs the measurement, through the control performed by the switching control section.

In such a configuration, the presence or absence of the connection of the detector can be determined without any trouble while the effect of noise on measurement is reduced by turning the detection function on/off as needed.

### BRIEF DESCRIPTION OF DRAWINGS

FIG. 1 schematically illustrates a surface texture measuring machine including a detector detection device according to a first exemplary embodiment.

FIG. 2 schematically illustrates a detection circuit and a control section according to the first exemplary embodiment.

FIG. 3 is a flowchart illustrating a detector detection method of the first exemplary embodiment.

FIG. 4 is a schematic diagram of the detection circuit of the first exemplary embodiment, illustrating a case where a detector is connected to a connector.

FIG. 5 is a graph, (A) illustrating a detecting signal, (B) to (E) respectively illustrating voltages at points A to D in the detection circuit of FIG. 4.

FIG. 6 is a schematic diagram of the detection circuit of the first exemplary embodiment, illustrating a case where the detector is not connected to the connector.

FIG. 7 is a graph, (A) to (D) respectively illustrating voltages at points A to D in the detection circuit of FIG. 6.

FIG. 8 is a graph, (A) to (D) respectively illustrating voltages at points A to D in a detection circuit of a comparative example, the points A to D corresponding to those of FIG. 7.

FIG. 9 schematically illustrates a surface texture measuring machine according to a second exemplary embodiment.

### DETAILED DESCRIPTION

### First Exemplary Embodiment

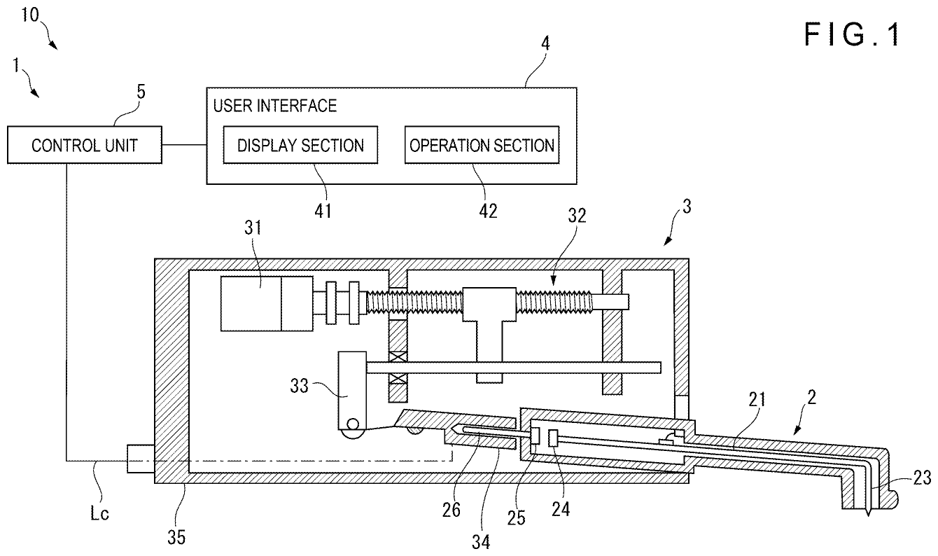

Referring to FIGS. 1 to 7, a detector detection device 1 according to an exemplary embodiment of the invention will be described. The detector detection device 1 of the exemplary embodiment, which is mounted on a surface texture measuring machine 10 in use, determines whether a detector 25 in the surface texture measuring machine 10 is electrically connected.

### Surface Texture Measuring Machine

First, a whole structure of the surface texture measuring machine 10 of the exemplary embodiment will be briefly described. As illustrated in FIG. 1, the surface texture measuring machine 10 includes a detecting unit 2 that detects displacement of a surface of a measurement target, a drive unit 3 that causes the detecting unit 2 to move, a user interface 4, and a control unit 5 that performs a variety of controls.

The surface texture measuring machine 10 measures a surface texture of the measurement target by measuring, along a surface of the measurement target, displacement in an up-down direction (Z direction) of the surface of the measurement target.

The detecting unit 2 includes an arm 21 swingable around a fulcrum, a stylus 23 provided to protrude at a first end of the arm 21, a core 24 provided at a second end of the arm 21, the detector 25 that detects an amount of displacement in the Z direction of the core 24, and a plug 26 electrically connected to the detector 25.

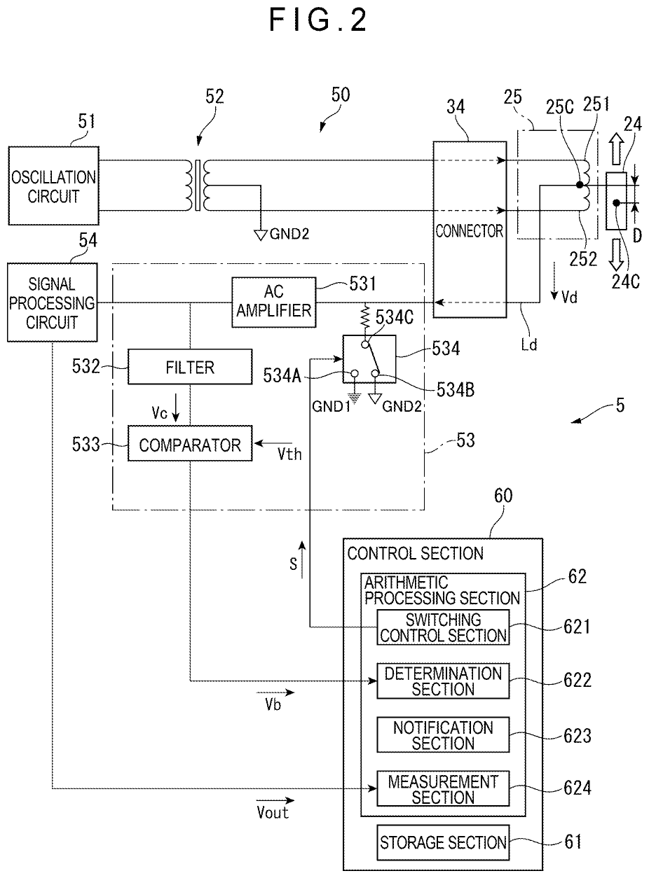

As illustrated in FIG. 2, the detector 25 of the exemplary embodiment, which is configured as a differential coil, includes two coils 251 and 252 in cumulative connection. The coils 251 and 252 are arranged in the Z direction. A signal output line Ld is connected to a midpoint 25c located between the two coils 251 and 252.

Movement of the core 24 in the Z direction varies a gap D in the Z direction between a core center 24c and the midpoint 25c located between the two coils 251 and 252. When an AC voltage (alternating voltage) generated from a later-described oscillation circuit 51 is applied to respective ends of the two coils 251 and 252, the impedance (inductance) of each of the two coils 251 and 252 changes depending on the gap D to generate a difference in induced voltage between the two coils 251 and 252. The detector 25 outputs, to the signal output line Ld, an AC voltage whose amplitude varies depending on the gap D, as a detecting signal Vd.

Although the plug 26 is omitted in FIG. 2, the plug 26 includes a plurality of terminals connected to the coils 251 and 252 of the detector 25 and the midpoint 25c. As illustrated in FIG. 1, in a state where the plug 26 is properly plugged in the connector 34, the terminals of the plug 26 are electrically connected to the control unit 5 via the connector 34.

The plug 26 of the exemplary embodiment is detachable from the connector 34. This allows for the replacement of the detecting unit 2 in the surface texture measuring machine 10 of the exemplary embodiment.

The drive unit 3 includes a motor 31, a feed screw mechanism 32 coupled to the motor 31, a slide portion 33 that moves in a measurement direction (X direction) orthogonal to the Z direction by means of the feed screw mechanism 32, the connector 34 supported by the slide portion 33, and a casing 35 that houses the drive unit 3.

The feed screw mechanism 32 has a known structure in which the connector 34 powered by the motor 31 moves in the X direction. The feed screw mechanism 32 is provided with an encoder that detects a movement amount in the X direction of the slide portion 33.

The connector 34 is configured to hold the detecting unit 2. When the slide portion 33 moves in the X direction by means of the feed screw mechanism 32, the connector 34 and the detecting unit 2 move in the X direction together with the slide portion 33. Further, the connector 34 is connected to a wiring group Lc extending from the control unit 5.

The user interface 4 includes a display section 41 on which a variety of information is displayed and an operation section 42 that receives a user's input operation. The operation section 42 may be an operation button(s) or a touch display configured together with the display section 41.

### Control Unit

As illustrated in FIG. 2, the control unit 5 includes a circuit section 50 and a control section 60. The circuit section 50 includes the oscillation circuit 51, a balancing transformer 52, a detection circuit 53, and a signal processing circuit 54. The control unit 5 includes a board on which the circuit section 50 is mounted (not illustrated in the drawings). The board is provided with a first ground GND1 grounded to a frame and a second ground GND2 (analog ground) that serves as a reference electric potential of a variety of circuits. In the exemplary embodiment, the electric potential (first electric potential) of the first ground GND1 is 0 V, and the electric potential (second electric potential) of the second ground GND2 is a predetermined electric potential (e.g., +2.5 V) greater than 0 V.

The oscillation circuit 51 generates an AC voltage having a sine wave with opposite phases. The AC voltage generated by the oscillation circuit 51 is applied to both ends of the detector 25 via the balancing transformer 52 and the connector 34. The balancing transformer 52 is connected to the second ground GND2, making the reference electric potential of the detector 25 the electric potential of the second ground GND2.

The detection circuit 53 is connected to the signal output line Ld that connects the detector 25 and the signal processing circuit 54. The detection circuit 53 includes an AC amplifier 531, a filter 532, a comparator 533, and a switching section 534.

The AC amplifier 531 amplifies the amplitude of the detecting signal Vd. The detection circuit 53 and the signal processing circuit 54 share the AC amplifier 531. In other words, the signal output line Ld branches, at a downstream side of the AC amplifier 531, into a main line extending toward the signal processing circuit 54 and a branched line extending toward the filter 532.

The filter 532, which is connected to the branched line at the downstream side of the AC amplifier 531, attenuates an AC component (alternating component) of the detecting signal Vd amplified by the AC amplifier 531. The filter 532 may be a low-pass filter or the like that removes high-frequency components.

The comparator 533 compares an input voltage Vc input from the filter 532 and a predetermined threshold voltage Vth, and outputs the comparison result as a binary signal Vb. For instance, when the input voltage Vc is greater than or equal to the threshold voltage Vth, the comparator 533 outputs a HIGH signal (hereinafter referred to as an H signal) as the binary signal Vb. When the input voltage Vc is smaller than the threshold voltage Vth, the comparator 533 outputs a LOW signal (hereinafter referred to as an L signal) as the binary signal Vb.

The threshold voltage Vth is input to the comparator 533 by a threshold voltage generator (not illustrated in the drawings). It is only necessary for the threshold value Vth to be set between the electric potential (0 V) of the first ground GND1 and the electric potential (+2.5 V) of the second ground GND2. Preferably, the threshold value Vth is approximately a half of the electric potential of the second ground GND2.

The switching section 534 is configured as a 2-input 1-output multiplexer. The switching section 534 includes a first input terminal 534A connected to the first ground GND1, a second input terminal 534B connected to the second ground GND2, and an output terminal 534C connected to a line that is extended between the connector 34 and the AC amplifier 531. The switching section 534 connects one of the first input terminal 534A and the second input terminal 534B to the output terminal 534C based on a control signal S input from the control section 60 described later. Accordingly, the switching section 534 performs the switching of a reference electric potential of the detection circuit 53 between the electric potential of the first ground GND1 and the electric potential of the second ground GND2.

The signal processing circuit 54, which is connected to the main line at the downstream side of the AC amplifier 531, has a configuration similar to a signal processing circuit of any known surface texture measuring machine. For instance, the signal processing circuit 54 includes a circuit for forming a displacement signal Vout (DC signal) from the detecting signal Vd, a noise filter, an analog/digital conversion circuit, and the like. The displacement signal Vout after signal processing is output to the control section 60.

The control section 60 includes a storage section 61 including a memory or the like and an arithmetic processing section 62 including a microprocessor or the like. The arithmetic processing section 62 functions as a switching control section 621, a determination section 622, a notification section 623, and a measurement section 624 by reading and executing a program stored in the storage section 61.

The switching control section 621 controls a switching operation of the switching section 534.

The determination section 622 determines based on the binary signal Vb input from the detection circuit 53 whether the detector 25 is electrically connected to the connector 34.

The notification section 623 outputs the determination result of the determination section 622 to the display section 41 or the like.

The measurement section 624 calculates a surface texture of the measurement target based on the displacement signal Vout input from the signal processing circuit 54 and a movement amount in the X direction input from the encoder of the drive unit 3.

Among the above configurations, the detection circuit 53 and the determination section 622 constitute the detector detection device 1.

### Detector Detection Method

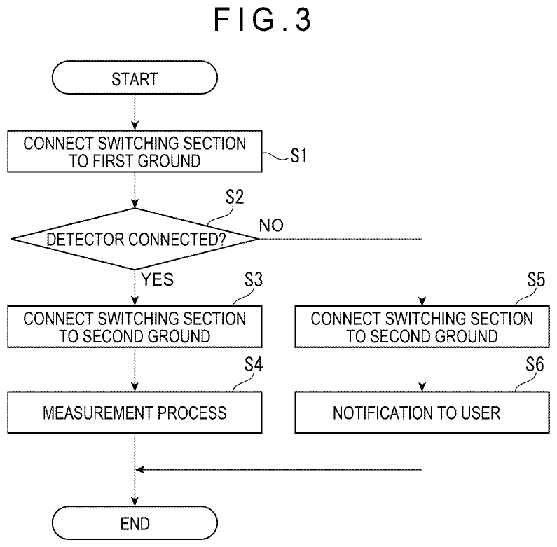

Referring to the flowchart of FIG. 3, a detector detection method for the surface texture measuring machine 10 of the exemplary embodiment will be described. For instance, the flowchart of FIG. 3 is started when the surface texture measuring machine 10 is turned on (or, when the surface texture measuring machine 10 receives an instruction to perform a measurement process that is input by a user's operation).

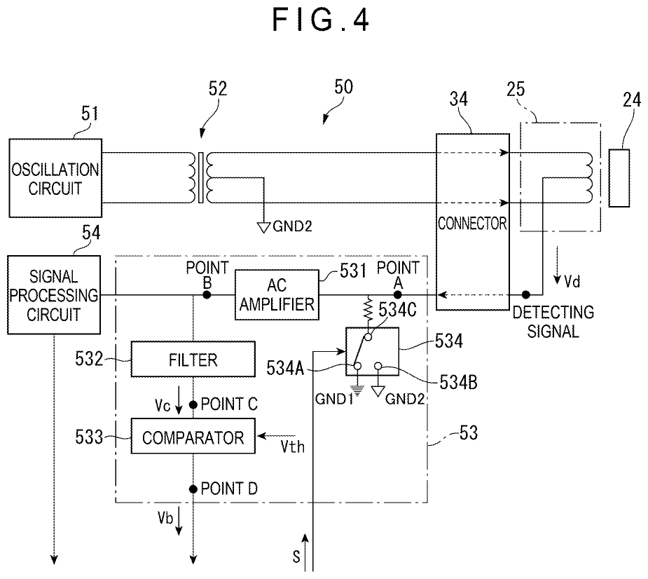

First, the switching control section 621 outputs the control signal S to the switching section 534, so that the output terminal 534C of the switching section 534 is connected to the first input terminal 534A (see, FIG. 4). The switching section 534 is thus connected to the first ground GND1 to make the reference electric potential of the detector 53 the electric potential (0 V) of the first ground GND1 (step S1). Thereby, a detection function comes into an ON state.

Subsequently, the determination section 622 determines based on the binary signal Vb input from the detection circuit 53 whether the detector 25 is electrically connected to the connector 34 (step S2).

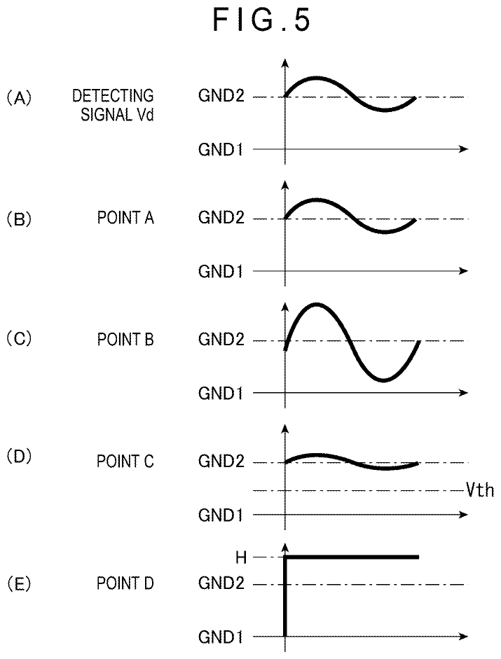

For instance, FIG. 4 illustrates a state where the detector 25 is electrically connected to the connector 34. For illustrative purposes, measurement points A to D are set in the detection circuit 53 of FIG. 4. Graphs of FIG. 5 (A) to FIG. 5 (E) illustrate a voltage of the detecting signal Vd from a point of time at which the surface texture measuring machine 10 is turned on (e.g., a voltage at a measurement point with the description “detecting signal” in FIG. 4) and voltages at the measurement points A to D in FIG. 4.

When the detector 25 is electrically connected to the connector 34, the detector 25 outputs the detecting signal Vd including an AC component of which reference electric potential is the second ground GND2 (see, FIG. 5 (A)). The detecting signal Vd is input from the detector 25 to the detection circuit 53 (see, FIG. 5 (B)). After the amplitude of the detecting signal Vd is amplified by the AC amplifier 531 (see, FIG. 5 (C)), the AC component of the detecting signal Vd is attenuated by the filter 532 (see, FIG. 5 (D)). The voltage of the detecting signal Vd with the attenuated AC component is input, as the input voltage Vc, to the comparator 533. Since the input voltage Vc is substantially equal to the reference electric potential of the detecting signal Vd (i.e., the second ground GND2), the input voltage Vc is higher than the threshold voltage Vth (see, FIG. 5 (D)). The comparator 533 compares the input voltage Vc and the threshold voltage Vth, and outputs the H signal as the binary signal Vb (see, FIG. 5 (E)). The determination section 622 determines based on the H signal that the detector 25 is electrically connected to the connector 34 (step S2: YES).

When it is determined as YES in the step S2, the switching control section 621 outputs the control signal S to the switching section 534, so that the output terminal 534C of the switching section 534 is connected to the second input terminal 534B (see FIG. 2, step S3). The switching section 534 is thus connected to the second ground GND2 to make the reference electric potential of the detection circuit 53 the electric potential (+2.5 V) of the second ground GND2. Thereby, the detection function comes into an OFF state.

After that, the measurement section 624 performs the measurement process in accordance with a user's instruction (step S4). Then, the flowchart in FIG. 3 ends.

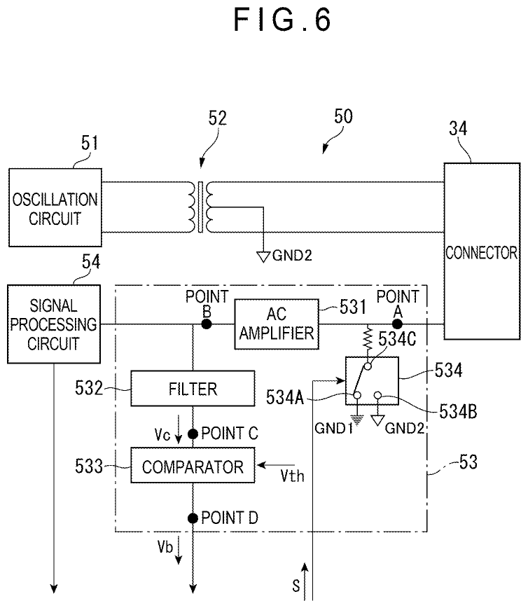

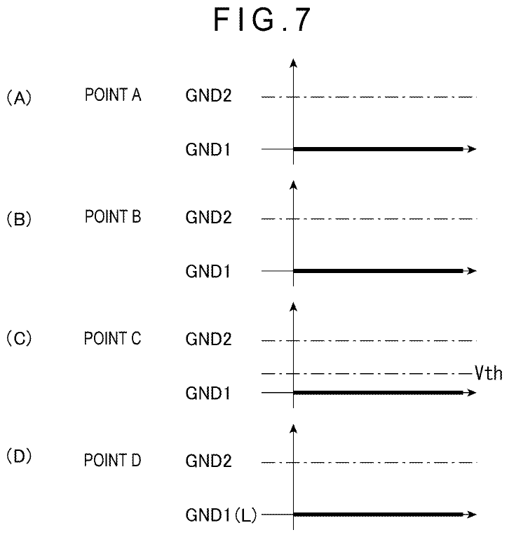

FIG. 6 illustrates a case where the detector 25 is not electrically connected to the connector 34 for some reason, such as a case where the plug 26 is not properly plugged in the connector 34. For illustrative purposes, measurement points A to D are set in the detection circuit 53 of FIG. 6, similarly to FIG. 4. Graphs of FIGS. 7 (A) to (D) illustrate voltages at the measurement points A to D, respectively.

When the detector 25 is not electrically connected to the connector 34, the detecting signal Vd to be input to the detection circuit 53 does not exist. Thus, the voltage at each of the measurement points A to C in the detection circuit 53 is the reference electric potential of the detection circuit 53, that is, the electric potential (0 V) of the first ground GND1 (see, FIGS. 7 (A) to (C)). Here, the electric potential (0 V) of the first ground GND1 is input, as the input voltage Vc, to the comparator 533. The input voltage Vc is smaller than the threshold voltage Vth (see, FIG. 7 (C)). The comparator 533 thus compares the input voltage Vc and the threshold voltage Vth, and outputs the L signal as the binary signal Vb (see, FIG. 7 (D)). The determination section 622 determines based on the L signal that the detector 25 is not electrically connected to the connector 34 (step S2: NO).

When it is determined as NO in the step S2, the switching control section 621 outputs the control signal S to the switching section 534, so that the output terminal 534C of the switching section 534 is connected to the second input terminal 534B (see FIG. 2, step S5). The switching section 534 is thus connected to the second ground GND2 to make the reference electric potential of the detection circuit 53 the electric potential (+2.5 V) of the second ground GND2. Thereby, the detection function comes into the OFF state.

After that, the notification section 623 outputs, to the display section 41 or the like, a notification indicating that the detector 25 is not electrically connected to the connector 34 (step S5). This allows a user to notice the poor connection of the detector 25. Then, the flowchart in FIG. 3 ends.

### Advantages of First Exemplary Embodiment

As described above, the detector detection device 1 of the exemplary embodiment includes the detection circuit 53 to which the detecting signal Vd is input, via the connector 34 of the surface texture measuring machine 10, from the detector 25 connected to the connector 34, and the determination section 622 that determines whether or not the detector 25 is connected to the connector 34, in which the detection circuit 53 includes the first ground GND1 having the first electric potential that is lower than the reference electric potential of the detector 25, and the comparator 533 that is connected to the first ground GND1, receives the detecting signal Vd from the connector 34, and compares the input voltage Vc and the predetermined threshold voltage Vth, and the determination section 622 determines based on the binary signal Vb output from the comparator 533 whether the detector 25 is connected to the connector 34.

Accordingly, whether the detector 25 is electrically connected to the connector 34 can be determined with a simple configuration without the necessity of complex algorithms.

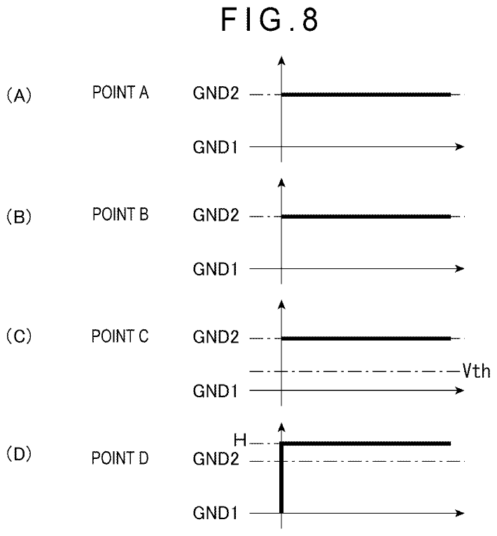

Here, a comparative example in which the reference electric potential of the detection circuit 53 is equal to the electric potential of the second ground GND2 will be described. The comparative example corresponds to a state where the detection function of the exemplary embodiment is in the OFF state, and the input voltage Vc to be input to the comparator 533 hardly changes depending on whether or not the detector 25 is connected. For instance, when the detector 25 is electrically connected to the connector 34, the voltages at the measurement points A, B, and C in the detection circuit 53 are as illustrated in FIG. 5. On the other hand, when the detector 25 is not electrically connected to the connector 34, the voltages at the measurement points A, B, and C in the detection circuit 53 are as illustrated in FIG. 8. Specifically, as illustrated in FIG. 8 (C), since the input voltage Vc to be input to the comparator 533 is equal to the electric potential of the second ground GND2, the input voltage Vc is higher than the threshold value Vth. The comparator 533 thus outputs the H signal as in the case where the detector 25 is electrically connected to the connector 34 (see, FIG. 8 (D)). Therefore, in the comparative example, the determination section 622 cannot determine that the detector 25 is not electrically connected to the connector 34.

In the exemplary embodiment, when the detection function is in the ON state, the reference electric potential of the detection circuit 53 is the electric potential of the first ground GND1. This makes a difference in the input voltage Vc to be input to the comparator 533 depending on whether or not the detector 25 is electrically connected to the connector 34. The comparator 533 is thus capable of outputting the binary signal Vb depending on whether or not the detector 25 is electrically connected to the connector 34. This allows the determination section 622 to determine based on the binary signal Vb whether the detector 25 is electrically connected to the connector 34.

Accordingly, a user easily understands the cause (i.e., poor connection between the connector 34 and the detector 25) of the measurement error in the surface texture measuring machine 10 including the detector detection device 1 of the exemplary embodiment. Further, the burden on the manufacturer of the measuring machine to respond to the inquiries is reducible.

Furthermore, the detector detection device 1 of the exemplary embodiment that eliminates the necessity of complex algorithms is achievable with a smaller number of components. The detector detection device 1 is thus easily incorporated into the downsized surface texture measuring machine 10.

In the exemplary embodiment, the detection circuit 53 includes the second ground GND 2 that supplies, as the reference electric potential of the detection circuit 53, the second electric potential that is equal to the reference electric potential of the detecting signal Vd, and the switching section 534 that is selectively connected to one of the first ground GND 1 and the second ground GND2 to perform switching of the reference electric potential of the detection circuit 53 between the first electric potential and the second electric potential. The arithmetic processing section 62 further includes the switching control section 621 that controls the switching operation performed by the switching section 534. The detector detection device 1 of the exemplary embodiment is thus configured to turn the detection function ON/OFF by performing the switching of the connection destination of the detection circuit 53 between the first ground GND1 and the second ground GND2.

For instance, the detection function comes into the ON state by connecting the switching section 534 to the first ground GND1 at the time of determination whether the detector 25 is connected. In this configuration, whether the detector 25 is connected can be detected using the detecting signal Vd flowing through the signal output line Ld.

Further, the detection function comes into the OFF state by connecting the switching section 534 to the second ground GND2 at the time of measurement. This inhibits the impact on measurement accuracy. Specifically, making the reference electric potential of the detection circuit 53 connected to the signal output line Ld equal to the reference electric potential of the detector 25 (=second ground GND2) reduces the effect of noise on the detecting signal Vd flowing through the signal output line Ld.

Thus, the processes such as the determination and the measurement are performed without any trouble by turning the detection function ON/OFF as needed in the exemplary embodiment.

The detection circuit 53 of the exemplary embodiment further includes the filter 532 that forms the input voltage Vc to be input to the comparator 533 by attenuating the AC component of the detecting signal Vd.

Such a configuration clearly defines the difference in the input voltage Vc based on the presence or absence of the connection of the detector 25, facilitating the setting of the threshold voltage Vth to be input to the comparator 533. Further, it is possible to more accurately determine whether the detector 25 is electrically connected.

In the exemplary embodiment, the first ground GND is grounded. Such a configuration makes a difference in the input voltage Vc based on the presence or absence of the connection of the detector 25 and reduces electric power consumed in the detection circuit 53. Such a configuration is especially effective when the surface texture measuring machine 10 is a handheld, battery-powered machine.

In the detection circuit 53 of the exemplary embodiment, the filter 532 and the comparator 533 are provided at the downstream side of the AC amplifier 531. If the filter 532 and the comparator 533 are provided at the upstream side of the AC amplifier 531, the effect of noise or the like to be added to the signal output line Ld from the filter 532 and the comparator 533 is amplified by the AC amplifier 531. As described above, the filter 532 and the comparator 533 are provided at the downstream side of the AC amplifier 531 in the exemplary embodiment. This inhibits the effect of noise or the like to be added from the filter 532 and the comparator 533 to the signal output line Ld from being amplified, and thus such an effect is minimized.

The case where the invention is applied to the detector 25 in an inductance type is described in the first exemplary embodiment. The invention, however, is applicable to a detector in an LVDT type, and an example thereof will be described in a second exemplary embodiment.

### Second Exemplary Embodiment

The surface texture measuring machine 10 of the second exemplary embodiment will be described. The surface texture measuring machine 10 of the second exemplary embodiment has substantially the same structure as that of the first exemplary embodiment except for a control unit 5A. In the description of the second exemplary embodiment, the same components as those in the first exemplary embodiment are denoted by the same reference signs and names to simplify or omit the description of the components.

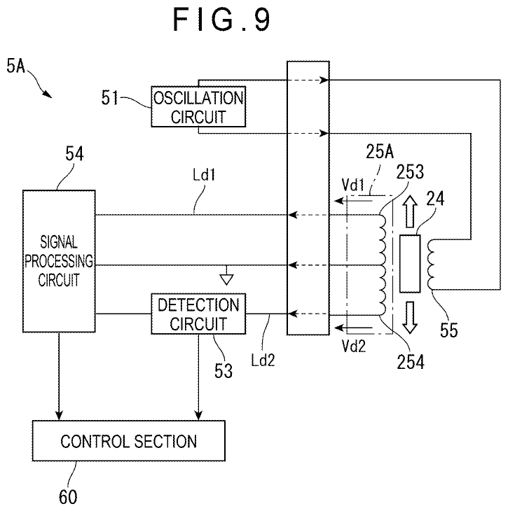

As illustrated in FIG. 9, the control unit 5A according to the second exemplary embodiment includes a detector 25A configured as a differential transformer. The detector 25A includes two secondary coils 253 and 254 arranged in the Z direction and connected differentially. Further, signal output lines Ld1 and Ld2 are respectively connected to the secondary coils 253 and 254.

When the AC voltage generated from the oscillation circuit 51 is applied to a primary coil 55, a voltage difference (differential voltage) is generated in the induced voltage of the secondary coils 253 and 254 depending on displacement of the core 24 in the Z direction. The detector 25A outputs, to the signal output lines Ld1 and Ld2, detecting signals Vd1 and Vd2 whose amplitudes vary depending on the displacement of the core 54.

In the second exemplary embodiment, the detection circuit 53 described in the first exemplary embodiment may be connected to one of the signal output lines Ld1 and Ld2. For instance, FIG. 9 illustrates the detection circuit 53 connected to the signal output line Ld2. Further, a detection method of the detector 25 in the second exemplary embodiment is the same as that in the first exemplary embodiment.

Also in the second exemplary embodiment, whether the detector 25A is electrically connected to the connector 34 can be determined with a simple configuration without the necessity of complex algorithms, similarly to the first exemplary embodiment.

### Modifications

The invention is not limited to the above exemplary embodiments, and configurations obtained through modifications, improvements, and the like are within the scope of the invention provided that the object of the invention is achievable.

In the above exemplary embodiments, the first ground GND1 is not limited to the ground potential (0 V). The first ground GND1 may have any electric potential lower than the electric potential of the second ground GND2.

In the above exemplary embodiments, the detection circuit 53 may not include the AC amplifier 531. For instance, the detecting signal Vd input to the detection circuit 53 may be input to the filter 532 without being amplified.

In the above exemplary embodiments, the detection circuit 53 may not include the filter 532. In such a case, the comparator 533 can properly output the binary signal Vb provided that the threshold voltage Vth is set between the lower limit of the amplitude of the input voltage Vc derived from the detecting signal Vd and the electric potential of the first ground GND1.

In the above exemplary embodiments, the switching section 534 may not switch the connection destination to the second ground GND2 at the time of measurement performed by the measurement section 624, and the connection of the first ground GND may be maintained. In other words, the detection circuit 53 may not include the switching section 534, and may be connected to the first ground GND1. Although the noise due to the electric potential difference between the reference electric potential of the detector 25 and the first ground GND1 may be generated at the time of measurement performed by the measurement section 624 in such a modification, measurement is possible if high accuracy is not required.

The case where the detector detection device 1 is used in the surface texture measuring machine 10 is described in each of the above exemplary embodiments. The invention, however, is not limited thereto. In other words, the detector detection device of the invention is usable in any measuring machine to/from which the detector is attachable/removable.

What is claimed is:

1. A detector detection device, comprising:
a detection circuit to which a detecting signal is input, via a connector of a measuring machine, from a detector connected to the connector; and
a determination section configured to determine whether or not the detector is connected to the connector, wherein
the detection circuit comprises a first ground having a first electric potential that is lower than a reference electric potential of the detector and a comparator that is electrically connected to the first ground and that is configured to receive the detecting signal from the connector and compare an input voltage and a predetermined threshold voltage, and
the determination section is configured to determine based on a binary signal output from the comparator whether the detector is connected to the connector.

2. The detector detection device according to claim 1, wherein
the detection circuit further comprises a second ground having a second electric potential that is equal to the reference electric potential of the detector and a switching section that is selectively connected to one of the first ground and the second ground and is configured to perform switching of a reference electric potential of the comparator between the first electric potential and the second electric potential, and
the detector detection device further comprises a switching control section configured to control the switching performed by the switching section.

3. The detector detection device according to claim 1, wherein the detection circuit further comprises a filter that is configured to form the input voltage to be input to the comparator by attenuating an AC component of the detecting signal.

4. The detector detection device according to claim 1, wherein the first ground has a ground potential.

5. A measuring machine comprising:
the detector detection device according to claim 1;
the connector;
the detector that is removably connected to the connector and is configured to output the detecting signal depending on displacement of a surface of a measurement target; and
a measurement section configured to measure a surface texture of the measurement target based on the detecting signal output from the detector.

6. A measuring machine comprising:
the detector detection device according to claim 2;
the connector;
the detector that is removably connected to the connector and is configured to output the detecting signal depending on displacement of a surface of a measurement target; and
a measurement section configured to measure a surface texture of the measurement target based on the detecting signal output from the detector, wherein
the switching section is connected to the first ground in a case where the determination section performs the determination and is connected to the second ground in a case where the measurement section performs the measurement, through the control performed by the switching control section.
